(19) United States
(12) Patent Application Publication
(10) Pub. No.: US 2026/0185204 A1
(43) Pub. Date: Jul. 2, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventors: Shigeru YAMAMOTO, Kyoto (JP); Keiji IWATA, Kyoto (JP); Daiki FUJII, Kyoto (JP); Kazuki GODA, Kyoto (JP); Yasuhiko NAGAI, Kyoto (JP)

(21) Appl. No.: 19/126,547

(22) PCT Filed: Oct. 17, 2023
(86) PCT No.: PCT/JP2023/037538

§ 371 Date: May 1, 2025

(30) Foreign Application Priority Data
Nov. 1, 2022 (JP) 2022-175425

(51) Int. Cl. C23C 14/02; C23C 14/24

(52) U.S. Cl. CPC C23C 14/021; C23C 14/24

(57) ABSTRACT

There is provided a substrate processing apparatus enabling a water repellent-derived adverse effect to be prevented from affecting a substrate. According to a substrate processing apparatus of the present invention, when water-repellent processing is performed on substrates, water repellent vapor supplied toward a processing tank positioned in a chamber is collected in an opening portion in an upper portion of the processing tank and discharged outside the chamber via an exhaust port. With such a configuration, the water repellent vapor does not flow around to reach a side wall of the chamber, and water repellent residues do not adhere to the side wall of the chamber. According to the present invention, it is possible to provide the substrate processing apparatus capable of maintaining the cleanliness of the substrates without allowing the water repellent residues to have adverse effects on the substrates.

### TECHNICAL FIELD

The present invention relates to a substrate processing apparatus and a substrate processing method, which perform predetermined processing on various substrates such as a semiconductor substrate, a substrate for a flat panel display (FPD) such as a liquid crystal display or an organic electroluminescence (EL) display device, a glass substrate for a photomask, and a substrate for an optical disk.

### BACKGROUND ART

Patent Literature 1 discloses a substrate processing method for processing a substrate accommodated in a chamber. The substrate processing method is performed by including a tank for immersing a substrate in a predetermined liquid, an ejection port through which an inert gas, an organic solvent vapor, and a water repellent vapor are supplied into a chamber, and a pressure reducing portion that reduces a pressure in the chamber. According to the disclosure of Patent Literature 1, the water repellent vapor is supplied into the chamber while pressure reduction is performed. In this manner, a surface of the substrate is modified. In this configuration, residues of a water repellent adhering to the surface of the substrate due to the supply of the water repellent vapor are removed by immersing the substrate in a diluted organic solvent in a later process, thus having no adverse effects on the substrate.

Patent Literature 2 also discloses a substrate processing method similar to that of Patent Literature 1. The substrate processing method of Patent Literature 2 also includes a process of supplying water repellent vapor while pressure reduction is performed in a chamber. The effect of supplying a water repellent while the pressure reduction is performed is that the water repellent can be easily supplied in a vapor state into the chamber.

### CITATION LIST

### Patent Literature

Patent Literature 1: JP 2022-27089 A
Patent Literature 2: JP 2018-56155 A

### SUMMARY OF INVENTION

### Technical Problem

However, according to the above-described configurations, a problem arises in that it is not possible to sufficiently prevent the water repellent from having an adverse effect on the substrates. That is, when a water repellent vapor is supplied into a chamber, water repellent residues adhere not only to a surface of the substrates but also to an inner wall of the chamber. Regarding the inner wall of the chamber, however, a portion thereof corresponding to a bottom portion of the chamber is positioned below a liquid level of the diluted organic solvent when the diluted organic solvent is accommodated in the chamber. Hence, water repellent residues attached to this portion are removed. However, water repellent residues remain on the other portions of the inner wall of the chambers, and this may adversely affect the substrates.

The present invention has been made in view of such circumstances, and an object of the present invention is to provide a substrate processing apparatus and a substrate processing method enabling water repellent-derived adverse effects to be prevented from affecting a substrate.

### Solution to Problem

In order to achieve such an object, the present invention has the following configuration.

A substrate processing apparatus continuously performs water-repellent processing, cleaning processing, and drying processing on a plurality of substrates, the substrate processing apparatus including: a sealable chamber; a processing tank that is provided in the chamber, stores a cleaning liquid, and has an open upper portion; a lifter that holds a plurality of substrates and moves up and down between an internal position in the processing tank and a position above the processing tank; draining means for draining the cleaning liquid stored in the processing tank; processing tank pressure-reducing means for evacuating the chamber by reducing a pressure in the processing tank; water repellent supplying means for supplying a water repellent to the substrates at a position above the processing tank; and control means for controlling a series of processings for the plurality of substrates, in which, in a process of performing the water-repellent processing on the plurality of substrates, the control means causes the water repellent supplying means to supply the water repellent to the substrates at the position above the processing tank while evacuating the chamber by causing the draining means to drain a processing liquid in the processing tank, and subsequently causing the processing tank pressure-reducing means to reduce a pressure in the processing tank.

[Operation and Effects] In the substrate processing apparatus according to (1) described above, in the process of performing the water-repellent processing on the plurality of substrates, the water repellent supplying means supplies a water repellent vapor to the substrates at the position above the processing tank while the chamber is evacuated by draining the processing liquid in the processing tank and emptying the processing tank by the draining means, and subsequently reducing the pressure in the processing tank by the processing tank pressure-reducing means. That is, the water repellent vapor in the substrate processing apparatus according to the present invention rides the flow of the atmosphere which passes through an opening of the processing tank and reaches the inside of the processing tank. With such a configuration, when the water repellent vapor is supplied into the chamber, adherence of water repellent residues to an inner wall of the chamber is reduced. This is because the water repellent vapor is collected in the processing tank and cannot flow around to enter a space between an outer wall of the processing tank and the inner wall of the chamber. According to the present invention, reduction in amount of the water repellent residues remaining in the chamber and adverse effects thereof on the substrates is achieved.

The present invention also has the following characteristics.
(2) In the substrate processing apparatus according to (1), the processing tank pressure-reducing means may include an exhaust port formed in the processing tank, a piping having one end connected to the exhaust port, an on-off valve provided in a middle of the piping, and a pressure reducing pump connected to an other end of the piping, and when the control means causes the water repellent supplying means to supply the water repellent to the substrates at the position above the processing tank, the control means may open the on-off valve and discharges, from the exhaust port, the water repellent collected in the processing tank from an upper opening of the processing tank while causing the pressure reducing pump to perform pressure reduction.

[Operation and Effects] As described in (2), when the processing tank has the exhaust port through which the atmosphere in the processing tank passes, a flow of the atmosphere from the processing tank in a pressure reduction state to the outside of the processing tank can be generated, so that the water repellent vapor can be reliably prevented from flowing around and entering the space between the outer wall of the processing tank and the inner wall of the chamber.
(3) In the substrate processing apparatus according to (2), the exhaust port may be provided in a bottom portion of the processing tank.

[Operation and Effects] As described in (3), when the exhaust port is provided in the bottom portion of the processing tank, an air flow allowing the atmosphere in the processing tank to pass from the top to the bottom of the processing tank is generated, so that the atmosphere in the upper portion of the processing tank can be more reliably collected in the processing tank.
(4) The substrate processing apparatus according to (1) may further include organic solvent supplying means for supplying an organic solvent vapor into the chamber.

[Operation and Effects] As described in (4), even with the configuration in which the organic solvent vapor is supplied into the chamber, the occurrence of adverse effects on cleanliness of the substrates due to particles generated through a reaction between the organic solvent and the water repellent is reduced. This is because, according to the present invention, the amount of water repellent remaining on the inner wall of the chamber is reduced.
(5) In the substrate processing apparatus according to (2), the exhaust port may also allow a liquid held in the processing tank to pass therethrough.

[Operation and Effects] As described in (5), when the exhaust port is configured to function as a drain port, there is no need to provide the drain port for draining a liquid from the processing tank, separately from the exhaust port. According to this configuration, it is possible to provide the substrate processing apparatus that has a simpler apparatus configuration and is easily manufactured and maintained.
(6) There is provided a substrate processing method for continuously performing water-repellent processing, cleaning processing, and drying processing on a plurality of substrates, in which a process of the water-repellent processing includes a processing tank pressure reducing process of evacuating a chamber in which a processing tank is provided by reducing a pressure in the processing tank having an opening at an upper portion through which a plurality of substrates are introduced, and a water repellent supplying process of supplying the water repellent to the plurality of substrates positioned at the upper portion of the processing tank while the processing tank pressure reducing process is executed.

[Operation and Effects] The substrate processing method according to (6) includes: a suction starting process of starting suction of the atmosphere in the processing tank having, in an upper portion, an opening through which a plurality of substrates are introduced; and a water repellent supplying process of supplying the water repellent vapor from the upper portion of the processing tank during suction operation. According to the present invention, the water repellent vapor is collected in the opening of the processing tank and discharged outside the chamber. With such a configuration, when the water repellent vapor is supplied into the chamber, adherence of water repellent residues to an inner wall of the chamber is reduced. This is because the water repellent vapor is collected in the processing tank and cannot flow around to enter a space between an outer wall of the processing tank and the inner wall of the chamber. According to the present invention, reduction in amount of the water repellent residues remaining in the chamber and adverse effects thereof on the substrates is achieved.
(7) The substrate processing method according to (6) may include a cleaning process of cleaning the processing tank with a liquid after the water repellent supplying process.

[Operation and Effects] The substrate processing method according to (7) may include the cleaning process of cleaning the processing tank with the liquid after the water repellent supplying process. In this manner, the cleanliness of the substrates can be further enhanced.
(8) The substrate processing method according to (6) may include an organic solvent supplying process of supplying an organic solvent to the processing tank after the water repellent supplying process.

[Operation and Effects] The substrate processing method according to (8) may include the organic solvent supplying process of supplying the organic solvent to the processing tank after the water repellent supplying process. Even with such a configuration, the cleanliness of the substrates is not adversely affected by particles generated by a reaction between the organic solvent and the water repellent. This is because, according to the present invention, the water repellent does not remain on the inner wall of the chamber.

### Advantageous Effects of Invention

According to a substrate processing apparatus of the present invention, when water-repellent processing is performed on substrates, water repellent vapor supplied toward a processing tank positioned in a chamber is collected in an opening at an upper portion of the processing tank and discharged outside the chamber. With such a configuration, the water repellent vapor does not flow around to reach an outer wall of the processing tank or a side wall of the chamber, and water repellent residues do not adhere to the outer wall of the processing tank or the side wall of the chamber. According to the present invention, it is possible to provide the substrate processing apparatus capable of maintaining the cleanliness of the substrates without allowing the water repellent residues to have adverse effects on the substrates. Also, according to a substrate processing method of the present invention, the water repellent vapor is collected in the opening of the processing tank and discharged. With such a configuration, when the water repellent vapor is supplied into the chamber, the water repellent residues do not adhere to the side wall of the chamber. This is because the water repellent vapor is collected in the processing tank and cannot flow around to enter a space between the outer wall of the processing tank and an inner wall of the chamber.

### BRIEF DESCRIPTION OF DRAWINGS

FIG. 1 is a functional block diagram illustrating a configuration of a substrate processing apparatus according to an embodiment.

FIG. 2 is a flowchart illustrating substrate processing according to the embodiment.

FIG. 3 is a schematic view specifically illustrating the substrate processing according to the embodiment.

FIG. 4 is a schematic view specifically illustrating the substrate processing according to the embodiment.

FIG. 5 is a schematic view specifically illustrating the substrate processing according to the embodiment.

FIG. 6 is a schematic view specifically illustrating the substrate processing according to the embodiment.

FIG. 7 is a schematic view specifically illustrating the substrate processing according to the embodiment.

FIG. 8 is a schematic view specifically illustrating the substrate processing according to the embodiment.

FIG. 9 is a schematic view specifically illustrating the substrate processing according to the embodiment.

FIG. 10 is a view illustrating an effect in a configuration of the embodiment.

FIG. 11 is a schematic view illustrating one modification embodiment of the present invention.

FIG. 12 is a schematic view illustrating the one modification embodiment of the present invention.

### DESCRIPTION OF EMBODIMENTS

Hereinafter, embodiments of the present invention will be described with reference to the drawings. A substrate processing apparatus according to the present invention is related to batch processing of continuously performing water-repellent processing, cleaning processing, and drying processing on a plurality of substrates. Substrate processing of the present invention is, for example, a part of a process of producing a device by forming a circuit on a substrate surface. The purity of liquid pure water (pure water), a liquid organic solvent, an inert gas, an organic solvent vapor, a water repellent vapor, and the like in the present specification is high to the extent that substrate processing is not affected thereby. Pure water and the liquid organic solvent are examples of a cleaning liquid of the present invention.

### EMBODIMENTS

### 1. Overview of Substrate Processing Apparatus

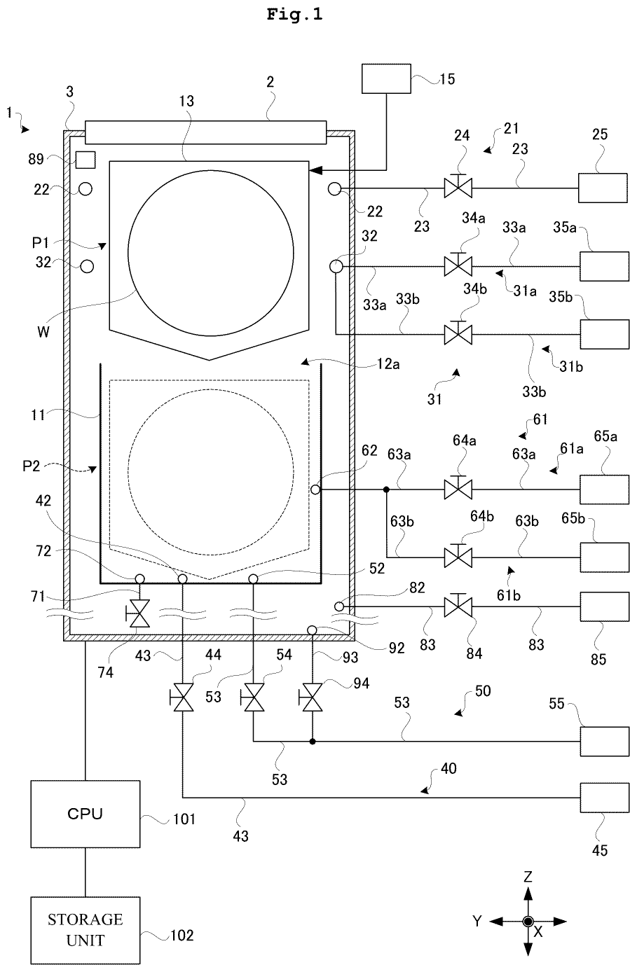

FIG. 1 is a schematic diagram illustrating an overview of a substrate processing apparatus 1 according to an embodiment. The substrate processing apparatus 1 of the present embodiment increases throughput of substrate processing by collectively performing the same substrate processing on a plurality of substrates W constituting a lot. The lot of the present embodiment is formed by arranging disk-shaped substrates W at predetermined intervals in a thickness direction of the substrate W. Specific examples of the substrate processing according to the present embodiment include water-repellent processing, cleaning processing, and drying processing of the substrate.

The substrate W has a circuit pattern on a surface thereof. The circuit pattern is formed on one surface side (front side) of the substrate W. The surface of the substrate W on which the circuit pattern is provided is referred to as a device surface.

The substrate processing apparatus 1 includes a chamber 3 capable of accommodating the lot. When various kinds of substrate processing are performed by the substrate processing apparatus 1, the lot is accommodated in the chamber 3 and subjected to processing in a space in the chamber 3. An upper end of the chamber 3 is an opening portion, and the lot can be accommodated in the chamber 3 through the opening portion or taken out of the chamber 3. The chamber 3 includes a door 2 capable of closing the opening portion. The door 2 is opened when the lot is moved in and out of the chamber 3 and is closed when the lot is subjected to the substrate processing. When the door 2 is opened, an inside of the chamber 3 communicates with the outside. When the door 2 is closed, the inside of the chamber 3 is sealed. Hence, the substrate processing for the lot is performed in the chamber 3 in the sealed state.

A processing tank 11 capable of holding a liquid is provided in a lower portion of an inner space of the chamber 3. The processing tank 11 is open upward and has an opening portion 12a at an upper portion thereof. Through the opening portion 12a, the lot can be positioned in the processing tank 11 or can be taken out of the processing tank 11. The processing tank 11 corresponds to a processing tank of the present invention.

A configuration of a processing tank pressure-reducing unit 40 that discharges the atmosphere in the processing tank 11 will be described. A processing tank exhaust port 42 used for performing pressure reduction of the inside of the processing tank 11 is provided at a bottom portion of the processing tank 11. The processing tank exhaust port 42 is connected to an exhaust valve 44 through a piping 43 and can allow or prohibit passing of gas through the processing tank exhaust port 42 by controlling the exhaust valve 44. A pressure reducing pump 45 for performing pressure reduction of the inside of the processing tank 11 is provided downstream of the exhaust valve 44. When the pressure reducing pump 45 is operated in a state in which the exhaust valve 44 is opened, a gas flow in which the atmosphere in the processing tank 11 is discharged to the outside of the chamber 3 through the processing tank exhaust port 42 is generated. When the processing tank 11 holds a liquid, the exhaust valve 44 is in a closed state, and the pressure reducing pump 45 does not reduce a pressure in the tank. The processing tank exhaust port 42 corresponds to an exhaust port of the present invention. The exhaust valve 44 corresponds to an on-off valve of the present invention. The pressure reducing pump 45 corresponds to pressure reducing means of the present invention.

A configuration of a drain unit 50 that drains a cleaning liquid in the processing tank 11 will be described. A processing tank drain port 52 for discharging a processing liquid in the processing tank 11 is provided at the bottom portion of the processing tank 11. The processing tank drain port 52 is connected to a liquid drain valve 54 through a piping 53 and can allow or prohibit passing of the processing liquid through the processing tank drain port 52 by controlling the liquid drain valve 54. A drain pump 55 that discharges a liquid from the processing tank 11 is provided downstream of the liquid drain valve 54. When the drain pump 55 is operated in a state in which the liquid drain valve 54 is opened, the liquid in the processing tank 11 is discharged to the outside of the chamber 3 through the processing tank drain port 52. When the processing tank 11 holds the liquid, the liquid drain valve 54 is in a closed state, and the drain pump 55 does not discharge the liquid in the tank. The processing tank drain port 52 is provided at the deepest portion of the processing tank 11 to enable all the liquid held in the processing tank 11 to be discharged.

A communication port 72 through which the liquid in the processing tank 11 is discharged to a bottom portion of the chamber 3 is provided at the bottom portion of the processing tank 11. Hence, the liquid held in the processing tank 11 may be discharged from the above-described processing tank drain port 52 to the outside of the processing tank 11 or may be discharged from the communication port 72 to the outside of the processing tank 11. The communication port 72 is provided at the deepest portion in the bottom portion of the processing tank 11 to enable all the liquid in the processing tank 11 to be discharged. The communication port 72 communicates with a passage 71 extending toward an outer side of the processing tank 11. A liquid drain valve 74 is provided at an end portion of the passage 71 on a discharge side. Hence, the liquid drain valve 74 is provided in a space formed between the processing tank 11 and the bottom portion of the chamber 3. When the liquid is held in the processing tank 11, the liquid drain valve 74 is in a closed state. On the other hand, when the liquid held in the processing tank 11 is quickly discharged from the processing tank 11, the liquid drain valve 74 is in an open state. Also, when the above-described exhaust valve 44 is opened, the liquid drain valve 74 is closed.

A lifter 13 that holds a plurality of substrates W (a lot) is provided in an upper portion of the inner space of the chamber 3. The lifter 13 holds the individual substrates W constituting the lot in a substantially vertical posture. Hence, the lifter 13 holds the substrates W in the vertical posture in a state in which the substrates are arranged in a thickness direction X (a horizontal direction: a direction orthogonal to a vertical direction Z) of the substrates W. In FIG. 1, a direction orthogonal to both the direction X and the direction Z is described as a direction Y.

In the chamber 3, a lifting/lowering mechanism 15 which lifts and lowers the lifter 13 is provided. Hence, by controlling the lifting/lowering mechanism 15, the lot above the processing tank 11 can be taken into the processing tank 11. That is, in the present embodiment, the lifter 13 can be lifted to make the lot stand by at a first position P1 set above the processing tank 11, or the lifter 13 can be lowered to place the lot at a second position P2 set in the processing tank 11. The substrates W constituting the lot placed at the first position P1 are entirely located above the processing tank 11 that holds the liquid (entirely located above a liquid level in the processing tank 11). The substrates W constituting the lot placed at the second position P2 are entirely located inside the processing tank 11 that holds the liquid (entirely located below the liquid level in the processing tank 11). In this manner, the lifter 13 holds the plurality of substrates W and moves up and down between an internal position (the second position P2) in the processing tank 11 and a position (the first position P1) above the processing tank 11.

The substrate processing apparatus 1 includes a plurality of gas supply units that supply gas and predetermined vapor to the chamber 3. Of the gas supply units, a gas supply unit 21 supplies, to an internal space of the chamber 3, water repellent vapor related to water repellency of a substrate surface. On the other hand, a gas supply unit 31 supplies an organic solvent vapor and an inert gas to the internal space of the chamber 3. An organic solvent may be a solvent enabling the wettability of the substrate W to be maintained, and an example thereof is isopropyl alcohol (IPA). The inert gas may be any gas having low reactivity, and an example thereof is nitrogen gas. The gas supply unit 31 corresponds to organic solvent supplying means of the present invention.

Examples of water repellents according to the embodiment include alkyldisilazanes (silylamines) such as hexamethyldisilazane (HMDS) and fluorides such as fluoroalkylchlorosilane. That is, the water repellent that can be used in the present embodiment may be any water repellent that can be supplied as vapor to the substrates W, such as a silicon-based water repellent. The water-repellent processing in the present embodiment is sufficient as long as surfaces of the substrates W can be modified, and there is no need to always generate a water-repellent film on the substrate W.

The substrate processing apparatus 1 includes a liquid supply unit 61 which supplies a liquid to the processing tank 11 in the chamber 3. The liquid supply unit 61 can supply a solution such as pure water, a liquid organic solvent, an organic solvent diluted with water, or the like to the processing tank 11.

A pressure sensor 89 that detects a pressure inside the chamber 3 is provided on an inner wall of the chamber 3. The pressure sensor 89 is provided avoiding the bottom portion of the chamber 3 in which the liquid discharged from the processing tank 11 through the passage 71 is held. A detection signal output from the pressure sensor 89 is used to adjust opening degrees of various types of valves when the pressure in the chamber 3 is set to a predetermined value.

A chamber exhaust port 82 through which pressure reduction of the inside of the chamber 3 is performed and a pressure reducing pump 85 connected to the chamber exhaust port 82 through a piping 81 are provided on a side wall of the chamber 3. The chamber exhaust port 82 is provided avoiding the bottom portion of the chamber 3 in which the liquid discharged from the processing tank 11 through the passage 71 is held. An adjustment valve 84 is provided in the middle of the piping 81 and is closed in a case where liquid is held at the bottom portion of the chamber 3 or in a case where the pressure reduction of the inside of the chamber 3 is performed through the processing tank exhaust port 42. In a case where the inside of the chamber 3 is maintained at the atmospheric pressure or in a case where the pressure reduction of the inside of the chamber 3 is performed in the state in which the processing tank 11 holds a liquid, the adjustment valve 84 is opened.

In addition, the chamber 3 includes a chamber drain port 92 for discharging the liquid held at the bottom portion of the chamber 3 to the outside of the chamber 3. The chamber drain port 92 is connected to a drain valve 94 through a piping 93. The chamber drain port 92 is provided at the deepest portion in the bottom portion of the chamber 3 to enable all the liquid in the chamber 3 to be discharged. In a case where the liquid held in the bottom portion of the chamber 3 is discharged to the outside of the chamber 3, the drain valve 94 is opened and is closed in the other cases. The piping 93 is made to be further connected to the drain valve 94 and the above-described drain pump 55. Hence, the drain pump 55 is configured to promote drainage by suctioning the processing liquid from the processing tank 11 or the bottom portion of the chamber 3.

The chamber 3 includes a central processing unit (CPU) 101 that controls each of the valves, the door 2, the lifting/lowering mechanism 15, the pressure reducing pump 45, the drain pump 55, the pressure reducing pump 85, and the like, and a storage unit 102 that stores various items of information necessary for control. A specific configuration of the CPU 101 is not particularly limited. For example, one CPU 101 may be provided in the chamber 3, or a plurality of CPUs 101 may be provided for each control target. Also, a plurality of CPUs 101 that collectively realize a part of control necessary for operation of the chamber 3 may be provided. A specific configuration of the storage unit 102 is not particularly limited similarly to the CPU 101.

Hereinafter, specific configurations of the respective supply units will be described. The gas supply unit 21 that supplies the water repellent vapor into the chamber 3 has ejection portions 22 disposed in the chamber 3. The ejection portions 22 are provided above the processing tank 11 and are configured to eject the water repellent vapor. The ejection portions 22 are provided on both sides of a right side and a left side of the substrates W positioned at the first position P1, and the gas supply unit 21 is configured to simultaneously spray the water repellent vapor from the two right and left ejection portions 22 toward the center in the space in the chamber 3. The ejection portions 22 have a tubular shape with a plurality of ejection ports, and the ejection portions 22 actually spray water repellent vapors from the plurality of individual ejection ports. That is, the gas supply unit 21 is configured to supply the water repellent vapor to the substrates W at the position (the first position P1) above the processing tank 11.

The gas supply unit 21 includes a piping 23 that supplies water repellent vapor to the ejection portion 22, and a valve 24 that controls a spray amount of the water repellent vapor. A water repellent vapor supply source 25 includes a reservoir in which a water repellent is stored and a vaporizer that vaporizes the water repellent. The piping 23 is provided between the valve 24 provided upstream of the ejection portion 22 and the water repellent vapor supply source 25 provided further upstream of the valve 24, and allows water repellent vapor to pass from the water repellent vapor supply source 25 through the valve 24 to the ejection portion 22. When the valve 24 is opened, the water repellent vapor flows through the piping 23 and is sprayed from the ejection portion 22. When the valve 24 is closed, the flow of the water repellent vapor is stopped by the valve 24 and does not reach the ejection portion 22.

A structure of the gas supply unit 31 that supplies the inert gas or the like into the chamber 3 will be described. The gas supply unit 31 has ejection portions 32 disposed in the chamber 3. The ejection portions 32 are provided above the processing tank 11 and are configured to eject the inert gas or the organic solvent vapor. Similarly to the ejection portions 22 of the gas supply unit 21, the ejection portions 32 are provided on both sides of the right side and the left side of the substrates W positioned at the first position P1. The gas supply unit 31 is configured to simultaneously spray the inert gas or the organic solvent vapor from the two right and left ejection portions 32 toward the center in the space in the chamber 3. Similarly to the ejection portions 22, the ejection portions 32 have a tubular shape with a plurality of ejection ports through which gas is sprayed toward the substrates W, and are configured to simultaneously spray the gas from the right side and the left side of the substrates W.

The gas supply unit 31 includes an inert gas supply module 31a that supplies an inert gas to the ejection portion 32 and an organic solvent vapor supply module 31b that supplies the organic solvent vapor to the ejection portion 32. The inert gas supply module 31a includes a piping 33a through which the inert gas is supplied to the ejection portion 32 and a valve 34a which controls a spray amount of the inert gas. An inert gas supply source 35a has a gas tank in which liquefied inert gas is stored. The piping 33a is provided between the valve 34a provided upstream of the ejection portion 32 and the inert gas supply source 35a provided further upstream of the valve 34a, and allows the inert gas to pass from the inert gas supply source 35a through the valve 34a to the ejection portion 32. When the valve 34a is opened, the inert gas flows through the piping 33a and is sprayed from the ejection portion 32. When the valve 34a is closed, the flow of the inert gas is stopped by the valve 34a and does not reach the ejection portion 32.

The organic solvent vapor supply module 31b provided in the gas supply unit 31 has the same configuration as that of the inert gas supply module 31a. That is, the organic solvent vapor supply module 31b includes a piping 33b through which the organic solvent vapor is supplied to the ejection portion 32, and a valve 34b that controls a spray amount of the organic solvent vapor. An organic solvent vapor supply source 35b includes a reservoir in which a liquid organic solvent is stored and a vaporizer that vaporizes the organic solvent. The piping 33b is provided between the valve 34b provided upstream of the ejection portion 32 and the organic solvent vapor supply source 35b provided further upstream of the valve 34b, and allows the organic solvent vapor to pass from the organic solvent vapor supply source 35b through the valve 34b to the ejection portion 32. When the valve 34b is opened, the organic solvent vapor flows through the piping 33b and is sprayed from the ejection portion 32. When the valve 34b is closed, the flow of the organic solvent vapor is stopped by the valve 34b and does not reach the ejection portion 32.

As described above, the gas supply unit 31 includes the inert gas supply module 31a and the organic solvent vapor supply module 31b which share the ejection portion 32. The inert gas derived from the inert gas supply module 31a or the organic solvent vapor derived from the organic solvent vapor supply module 31b can be sprayed from the ejection portion 32. When the inert gas is sprayed from the ejection portion 32, the valve 34a provided in the inert gas supply module 31a is opened, and the valve 34b provided in the organic solvent vapor supply module 31b is closed. On the other hand, when the organic solvent vapor is sprayed from the ejection portion 32, the valve 34a provided in the inert gas supply module 31a is closed, and the valve 34b provided in the organic solvent vapor supply module 31b is opened.

Subsequently, the liquid supply unit 61 that supplies the liquid to the processing tank 11 will be described. The liquid supply unit 61 has a processing liquid supply port 62 disposed in the processing tank 11. The processing liquid supply port 62 ejects pure water and a liquid organic solvent to the processing tank 11. The liquid supply unit 61 includes a pure water supply module 61a that supplies pure water to the processing liquid supply port 62 and a liquid organic solvent supply module 61b that supplies a liquid organic solvent to the processing liquid supply port 62. The pure water supply module 61a includes a piping 63a through which the pure water is supplied to the processing liquid supply port 62 and a valve 64a that controls a release amount of the pure water. A pure water supply source 65a has a tank in which the pure water is stored. The piping 63a is provided between the valve 64a provided upstream of the processing liquid supply port 62 and the pure water supply source 65a provided further upstream of the valve 64a, and allows the pure water to pass from the pure water supply source 65a through the valve 64a to the processing liquid supply port 62. When the valve 64a is opened, the pure water flows through the piping 63a and is released from the processing liquid supply port 62. When the valve 64a is closed, the flow of the pure water is stopped by the valve 64a and does not reach the processing liquid supply port 62.

The liquid organic solvent supply module 61b provided in the liquid supply unit 61 has the same configuration as that of the pure water supply module 61a. That is, the liquid organic solvent supply module 61b includes a piping 63b through which the liquid organic solvent is supplied to the processing liquid supply port 62 and a valve 64b that controls a release amount of the liquid organic solvent. A liquid organic solvent supply source 65b has a reservoir in which the liquid organic solvent is stored. The piping 63b is provided between the valve 64b provided upstream of the processing liquid supply port 62 and the liquid organic solvent supply source 65b provided further upstream of the valve 64b , and allows the liquid organic solvent to pass from the liquid organic solvent supply source 65b through the valve 64b to the processing liquid supply port 62. When the valve 64b is opened, the liquid organic solvent flows through the piping 63b and is released from the processing liquid supply port 62. When the valve 64b is closed, the flow of the liquid organic solvent is stopped by the valve 64b and does not reach the processing liquid supply port 62.

As described above, the liquid supply unit 61 includes the pure water supply module 61a and the liquid organic solvent supply module 61b which share the processing liquid supply port 62. The pure water derived from the pure water supply module 61a or the liquid organic solvent derived from the liquid organic solvent supply module 61b can be released from the processing liquid supply port 62. When pure water is released from the processing liquid supply port 62, the valve 64a provided in the pure water supply module 61a is opened, and the valve 64b provided in the liquid organic solvent supply module 61b is closed. On the other hand, when the liquid organic solvent is released from the processing liquid supply port 62, the valve 64a provided in the pure water supply module 61a is closed, and the valve 64b provided in the liquid organic solvent supply module 61b is opened.

In the embodiment, the reservoir for the storage of the liquid organic solvent is provided in the liquid supply unit 61, separately from the reservoir for the storage of the liquid organic solvent which is provided in the gas supply unit 31. However, a configuration may be employed in which the gas supply unit 31 and the liquid supply unit 61 share the same reservoir.

### Flow of Substrate Processing

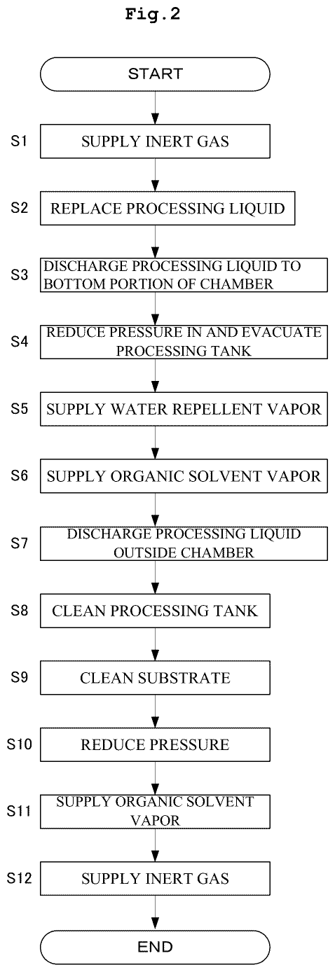

Hereinafter, the substrate processing using the substrate processing apparatus 1 according to the embodiment will be specifically described with reference to the flowchart according to FIG. 2. The substrate processing of the present embodiment is configured to perform various kinds of substrate processing on the lot supported by the lifter 13 at the second position P2. It is assumed that the pure water is held in the processing tank 11, and the door 2 is in the closed state. A pressure in the chamber 3 at this time is the atmospheric pressure.
Step S1: First, the inert gas is supplied into the chamber 3 by the gas supply unit 31. At this time, the inside of the chamber 3 is subjected to the pressure reduction via the chamber exhaust port 82 positioned at a lower side of the chamber 3, and the pressure in the chamber 3 is reduced. When such a state is maintained, the air in the chamber 3 is quickly replaced with the inert gas. In this manner, a highly reactive gas such as oxygen contained in the air is discharged to the outside of the chamber 3, and necessary preparation is completed before the various kinds of substrate processing subsequent to this step are performed. In the next step S2, the organic solvent vapor is supplied into the chamber 3. In this step, the pressure in the chamber 3 is reduced before the supply, so that the inert gas in the chamber 3 is diluted, and the inert gas in the chamber 3 is quickly replaced with the organic solvent vapor. It can be understood that the pressure reduction of the inside of the chamber 3 causes a part of the inert gas to be already released from the chamber 3 before the organic solvent vapor is supplied.

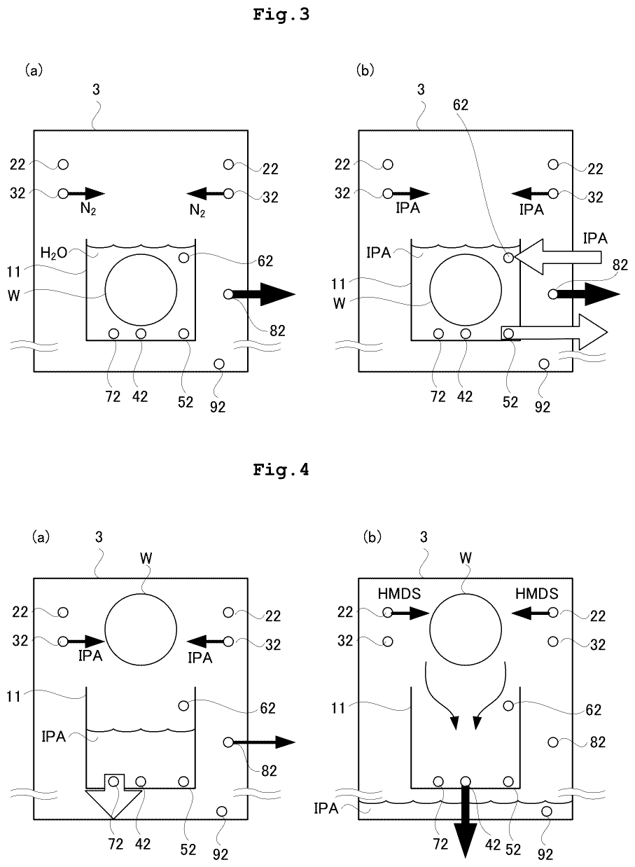

In this step, the inert gas supplied to the chamber 3 flows around to enter the processing tank 11 and reaches the chamber exhaust port 82. The inert gas is discharged from the chamber exhaust port 82 to the outside of the chamber 3. FIG. 3(a) illustrates the flow of gas in this step.
Step S2: Subsequently, while the liquid organic solvent is supplied to the processing tank 11 through the liquid supply unit 61, the pure water in the processing tank 11 is discharged from the processing tank drain port 52. By this operation, the pure water held in the processing tank 11 is gradually replaced with the liquid organic solvent. Hence, the lot on the second position P2 is immersed in the organic solvent. Also, in this step, the organic solvent vapor is supplied into the chamber 3 by the gas supply unit 31. At this time, the inside of the chamber 3 is subjected to the pressure reduction via the chamber exhaust port 82 positioned at the lower side of the chamber 3, and the pressure in the chamber 3 is reduced. When such a state is maintained, the inert gas in the chamber 3 is quickly replaced with the organic solvent vapor in accordance with the principle described in step S1 described above. In this manner, all the substrates W constituting the lot have the reliably maintained wettability. FIG. 3(b) illustrates the flow of the gas and the liquid in this step.
Step S3: The lot positioned at the second position P2 is lifted by the lifter 13 from the second position P2 and reaches the first position P1. When the liquid drain valve 74 is opened in this state, the liquid organic solvent held in the processing tank 11 quickly flows out to the bottom portion of the chamber 3 and is held therein. Meanwhile, the organic solvent vapor is supplied from the gas supply unit 31. At this time, since the pressure reducing pump 45 is not operated, the organic solvent vapor is naturally discharged by a supplied amount to the outside of the chamber 3 through the chamber exhaust port 82. Hence, the pressure in the chamber 3 in this step is equal to the atmospheric pressure. Hence, the liquid organic solvent held in the processing tank 11 is quickly discharged to the outside of the processing tank 11 without being affected by gas phase suction. This step is preparation for executing the next step S4. That is, in step S4, the pressure reduction is performed through the processing tank exhaust port 42 positioned at the bottom portion of the processing tank 11, but this operation is hindered by the liquid organic solvent held in the processing tank 11. In this step, it is possible to perform pressure reduction on the inside of the processing tank 11 from the processing tank exhaust port 42 by making the processing tank 11 empty. FIG. 4(a) illustrates the flow of the gas in this step.
Step S4: The pressure-reducing exhaust is started in the processing tank 11 through the processing tank exhaust port 42. When the inside of the processing tank 11 is subjected to the pressure-reducing exhaust, the chamber 3 is also in a pressure reduction state. As a result, the atmosphere in the chamber 3 is caused to flow into the processing tank 11 from the opening portion 12a in the upper portion of the processing tank 11 and reaches the processing tank exhaust port 42. In this manner, the processing tank pressure-reducing unit 40 reduces the pressure in the processing tank 11 which has become empty with drainage of the cleaning liquid, thereby exhausting gas in the chamber 3.
Step S5: The water repellent vapor is supplied into the chamber 3 from the gas supply unit 21 in a state in which the pressure-reducing exhaust in the processing tank 11 is continued. At this time, the inside of the chamber 3 is in the pressure reduction state. Hence, the atmosphere in the processing tank 11 is quickly replaced from the organic solvent vapor to the water repellent vapor in accordance with the same principle as the pressure-reducing operation according to step S1. The water repellent vapor supplied by the gas supply unit 21 rides the flow of gas generated due to the pressure-reducing exhaust in the processing tank 11 and is discharged to the outside of the chamber 3. Hence, the water repellent vapor supplied into the chamber 3 is collected in the opening portion 12a of the processing tank 11. In this way, it is possible for the substrate W not to be affected by particles, as compared with a configuration in which the water repellent vapor is suctioned from the chamber exhaust port 82. In a case where the water repellent vapor is suctioned from the chamber exhaust port 82, the water repellent vapor flows around to enter a space positioned between a side wall of the processing tank 11 and the side wall of the chamber 3 without being collected in the opening portion 12a of the processing tank 11. Then, the water repellents adhere to the side wall of the chamber 3 and an outer wall of the processing tank 11, and particles are generated in this part later. According to this step, since the water repellents are prevented from adhering to the side wall of the chamber 3 and the outer wall of the processing tank 11, particles are not generated in the part. Each of the substrates W exposed to the water repellent vapor has a hydrophobic surface changed from a hydrophilic surface, and the substrate surface is modified.

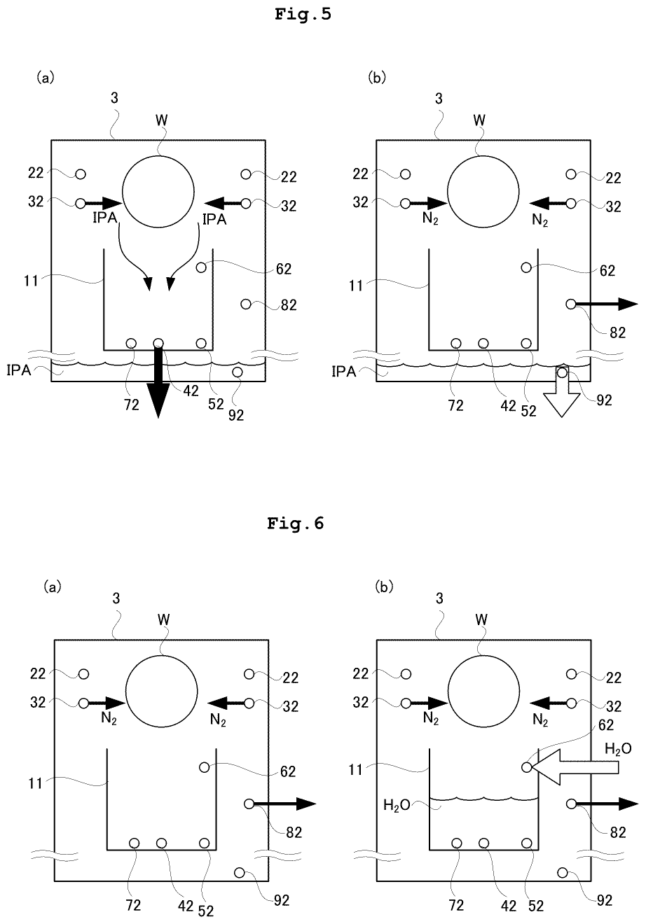

In this step, the inert gas is sprayed from the gas supply unit 31. A flow rate of the inert gas at this time is lower than a spray rate of the inert gas in step S1. By gently spraying the inert gas from the gas supply unit 31 in this manner, adverse effect due to backflow of the water repellent vapor in the chamber 3 to the gas supply unit 31 is not caused. The water repellent vapor and the organic solvent react with each other to generate particles. By spraying the inert gas from the ejection portion 32, particles adversely affecting the cleaning of the substrates W are not generated in the piping of the gas supply unit 31. FIG. 4(b) illustrates the flow of the gas in steps S4 and S5.
Step S6: The organic solvent vapor is supplied into the chamber 3 in a state in which the pressure reduction in the processing tank 11 is continued through the processing tank exhaust port 42. When the pressure in the processing tank 11 is reduced, the inside of the chamber 3 is in the pressure reduction state. Hence, the atmosphere in the processing tank 11 is quickly replaced from the water repellent vapor to the organic solvent vapor in accordance with the same principle as the pressure-reducing operation according to step S1. The organic solvent vapor supplied from the gas supply unit 31 rides the flow of the atmosphere from the opening of the processing tank 11 toward the processing tank exhaust port 42 and is discharged to the outside of the chamber 3. Hence, the organic solvent vapor supplied into the chamber 3 is collected in the opening portion 12a of the processing tank 11 and does not flow around to enter the space positioned between the side wall of the processing tank 11 and the side wall of the chamber 3. As a result, neither the water repellent vapor nor the organic solvent vapor reaches the space, so that particles are not generated on the side wall of the chamber 3 and the outer wall of the processing tank 11. FIG. 5(a) illustrates the flow of the gas in this step.

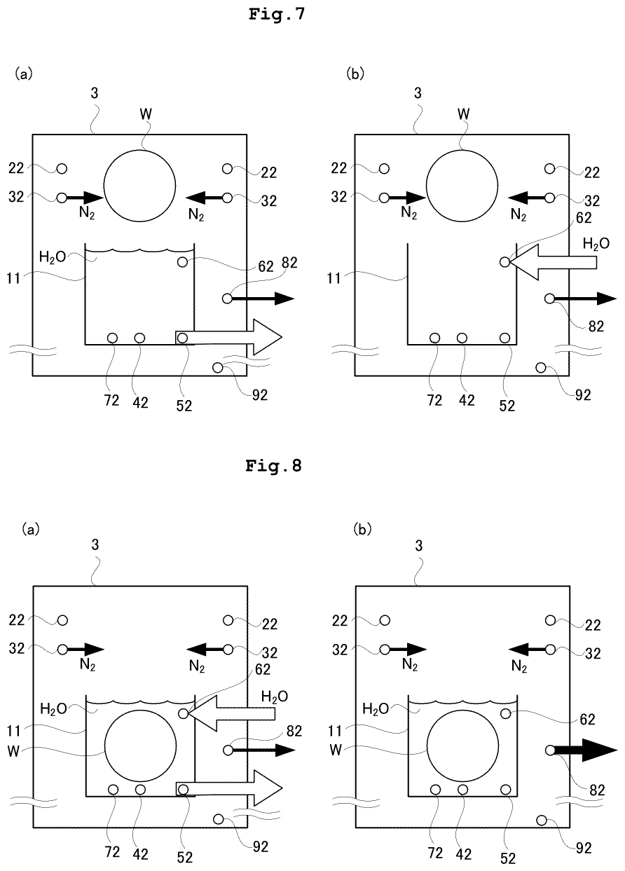

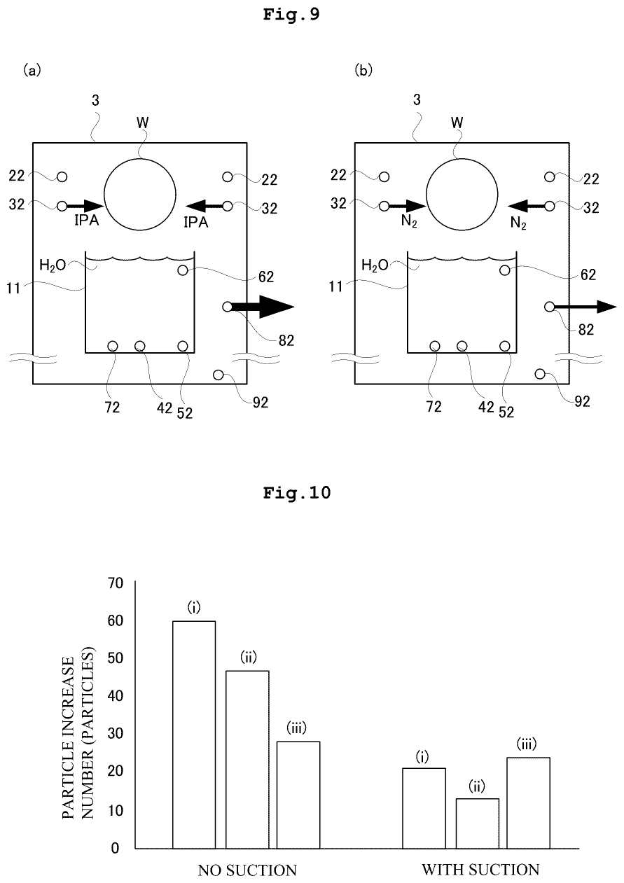

In this step, an excessive water repellent remaining on a surface of the substrates W reacts with the organic solvent vapor and forms particles to be released. Since the particles are removed in the subsequent cleaning process, there is no adverse effect on the cleanliness of the substrate W. On the other hand, when particles are generated on the side wall of the chamber 3 and the outer wall of the processing tank 11, the particles are not removed in the subsequent cleaning process. However, according to the present embodiment, adhesion of the particles to the side wall of the chamber 3 and the outer wall of the processing tank 11 is curbed by the exhaust of the inside of the chamber 11 through the processing tank 11.
Step S7: The drain valve 94 in the closed state is opened, and the liquid organic solvent held in the bottom portion of the chamber 3 is discharged from the chamber 3. In this step, the inert gas is supplied from the gas supply unit 31. At this time, since the pressure reducing pump 45 is not operated, the inert gas is naturally discharged by a supplied amount to the outside of the chamber 3 through the chamber exhaust port 82. Hence, the pressure in the chamber 3 in this step is equal to the atmospheric pressure, and the liquid organic solvent in the bottom portion of the chamber 3 is quickly discharged to the outside of the chamber 3 without being affected by gas phase suction. FIG. 5(b) illustrates the flows of the gas and the liquid in this step. This step may be performed under a pressure reduction condition. Hence, a process of discharging the liquid organic solvent in this process may be performed during steps S4 to S6 described above.
Step S8: The processing tank 11 is cleaned using pure water. During the corresponding processing, the lot takes shelter at the first position P1. The pressure in the chamber 3 in this step is the atmospheric pressure, and the inert gas is continuously supplied to the chamber 3. FIG. 6(a) illustrates a state in which the discharge of the liquid organic solvent performed in step S7 is ended. FIG. 6(b) illustrates a state in which the pure water is supplied into the processing tank 11. Consequently, a water level of the pure water held in the processing tank 11 rises, and as illustrated in FIG. 7(a), the processing tank 11 is filled with the pure water. From this state, the pure water in the processing tank 11 is discharged from the processing tank 11 through the processing tank drain port 52. In this manner, the particles adhering to the processing tank 11 are dissolved in the pure water and removed. The water repellent and the organic solvent adhere to the inner wall of the processing tank 11 before cleaning through steps S5 and S6 described above. Hence, both the water repellent and the organic solvent react with each other, and particles generated therefrom adhere to the inner wall. In step S8, a configuration is provided in which the processing tank 11 is cleaned to remove the particles from the inner wall of the processing tank 11.
Step S9: When the cleaning of the processing tank 11 is ended, the cleaning of the substrates W is performed to remove particles adhering to the substrates W. The pressure in the chamber 3 in this step is the atmospheric pressure, and the inert gas is continuously supplied to the chamber 3. First, the pure water is supplied to the empty processing tank 11. When the processing tank 11 is filled with the pure water, the lot placed at the first position P1 is lowered to the second position P2, and the individual substrates W constituting the lot are immersed in the pure water. In this state, while the pure water is supplied to the processing tank 11, the pure water in the processing tank 11 is discharged. In this step, the particles on the surfaces of the substrates W are dissolved and removed from the substrates W. Further, since pure water unused in the processing is continuously supplied to the processing tank 11 at all times, the cleanliness of the substrates W is further enhanced. FIGS. 7(b) and 8(a) illustrate the flows of the gas and the liquid in this step.
Step S10: The pressure reduction in the chamber 3 is started, and the inside of the chamber 3 is in the pressure reduction state. Also in this step, the inert gas is continuously supplied to the chamber 3. This step is preparation for executing the next step S11. In the next step S11, the organic solvent vapor is supplied into the chamber 3. In this step, the pressure in the chamber 3 is reduced before the supply, so that the inert gas in the chamber 3 is diluted, and the inert gas in the chamber 3 is quickly replaced with the organic solvent vapor. It can be understood that the pressure reduction of the inside of the chamber 3 causes a part of the inert gas to be already released from the chamber 3 before the organic solvent vapor is supplied. FIG. 8(b) illustrates the flow of the gas in this step.
Step S11: The organic solvent vapor is supplied into the chamber 3 while the inside of the chamber 3 is maintained in the pressure reduction state. Then, the atmosphere in the chamber 3 is quickly replaced from the inert gas to the organic solvent vapor in accordance with the same principle as the pressure-reducing operation according to step S1. The lot in the chamber 3 is exposed to the organic solvent vapor, and each of the substrates W constituting the lot is subjected to preliminary drying processing. In this step, the organic solvent vapor supplied to the chamber 3 flows around to enter the processing tank 11 and reaches the chamber exhaust port 82. Even with such a configuration, particles are not wound up from the side wall of the chamber 3 and the outer wall of the processing tank 11 and do not float in the chamber 3. This is because particles are not generated on the side wall of the chamber 3 and in the processing tank 11 of the present embodiment. When particles adhere to surfaces of the substrates W in this step, the particles remain without being removed, and this affects the quality of a device to be produced. However, according to the present embodiment, since particles do not float in the chamber 3 as a matter of course, such a circumstance does not occur. FIG. 9(a) illustrates the flow of the gas in this step.
Step S12: The inert gas is supplied into the chamber 3 in a state in which the inside of the chamber 3 is returned to the atmospheric pressure. Then, the organic solvent no longer adheres to the surfaces of the substrates W. In this manner, the preliminary drying of the substrates W constituting the lot is ended. Further, when the inert gas is continuously supplied into the chamber 3, the substrates W are gradually dried. The substrate processing according to the present embodiment is ended when the drying of the substrates W is completed. FIG. 9(b) illustrates the flow of the gas in this step.

As described above, in the process of performing the water-repellent processing in the substrate processing apparatus 1 of the present invention, the gas supply unit 21 supplies the water repellent vapor to the substrates W placed at the position (the first position P1) above the processing tank 11 while the chamber 3 is evacuated by draining the processing liquid in the processing tank 11 and emptying the processing tank 11 by the drain unit 50, and subsequently reducing the pressure in the processing tank 11 by the processing tank pressure-reducing unit 40. More specifically, the processing tank 11 in the substrate processing apparatus 1 has the processing tank exhaust port 42 through which the atmosphere inside the processing tank 11 passes, and the water repellent vapor is suctioned by the pressure reducing pump 45 from the processing tank exhaust port 42 when the water repellent vapor is supplied into the chamber 3. Then, the water repellent vapor collected in the processing tank 11 from the opening portion 12a in the upper portion of the processing tank 11 is discharged from the processing tank exhaust port 42. That is, the water repellent vapor ejected from the ejection portion 22 in the substrate processing apparatus 1 according to the present invention flows by riding the flow of the atmosphere which passes through the opening portion 12a of the processing tank 11 and reaches the processing tank exhaust port 42 provided in the processing tank 11. With such a configuration, when the water repellent vapor is supplied into the chamber 3, the water repellent residues such as the particles do not adhere to the side wall of the chamber 3 or the outer wall of the processing tank 11. This is because the water repellent vapor is collected in the processing tank 11 and cannot flow around to enter the space between the outer wall of the processing tank 11 and the inner wall of the chamber 3. According to the present invention, adverse effects due to the water repellent residues remaining on the side wall of the chamber 3 or the outer wall of the processing tank 11 and the particles derived therefrom do not affect the substrates W.

Subsequently, actual effects according to the present invention will be described. FIG. 10 illustrates a result of actual measurement of impact of particles on the substrate W. As illustrated in FIG. 10, in a case where the water repellent vapor is not suctioned in step S5, the number of particles having a diameter of 150 nm or larger is significantly increased as compared with that before the processing. In comparison, in the case where the water repellent vapor is suctioned in step S5, increase in the particles is reduced as compared with the case where the water repellent vapor is not suctioned although the number of particles having the diameter of 150 nm or larger is increased as compared with that before the processing. Note that (i) in FIG. 10 illustrates increase in the particles per unit area on the substrate W positioned at the first position in the lot, and (ii) illustrates increase in the particles per unit area on the substrate W positioned at the twenty-fifth position from the first position in the lot. In addition, (iii) of FIG. 10 illustrates increase in the particles per unit area on the substrate W positioned at the forty-third position from the first position in the lot. The lot includes 50 substrates W.

The present invention is not limited to the above-described embodiments and can be modified as follows.

### Modification Embodiment 1

The processing tank exhaust port 42 of the embodiment is provided in the bottom portion of the processing tank 11, but the present invention is not limited to this configuration, and the processing tank exhaust port 42 may be provided in the side wall of the processing tank 11. Even with such a configuration, the same effects as those of the embodiment are obtained.

### Modification Embodiment 2

In step S6 of the embodiment, there is no need to continuously maintain the pressure reduction in the chamber 3 during the entire period of the corresponding step. For example, the pressure in the chamber 3 may be set to the atmospheric pressure from the middle of step S6, and the organic solvent vapor supplied into the chamber 3 may be naturally discharged from the chamber exhaust port 82. In this manner, the liquid organic solvent held in the bottom portion of the chamber 3 in step S6 can be quickly discharged to the outside of the chamber 3.

### Modification Embodiment 3

In step S5 of the embodiment, the water repellent vapor is supplied into the chamber 3 in the state in which the substrates W are positioned at the first position P1, but the present invention is not limited to this configuration. The water repellent vapor may be supplied into the chamber 3 while the substrates W are made to reciprocate between the first position P1 and the second position P2. With such a configuration, since the water-repellent processing of the substrates W can be performed while a positional relationship between the ejection portion 22 of the water repellent vapor and the substrate W is changed, the water repellent vapor is reliably spread over the entire region of the substrate W. Hence, according to the present modification embodiment, more reliable water-repellent processing can be performed on the substrates W.

### Modification Embodiment 4

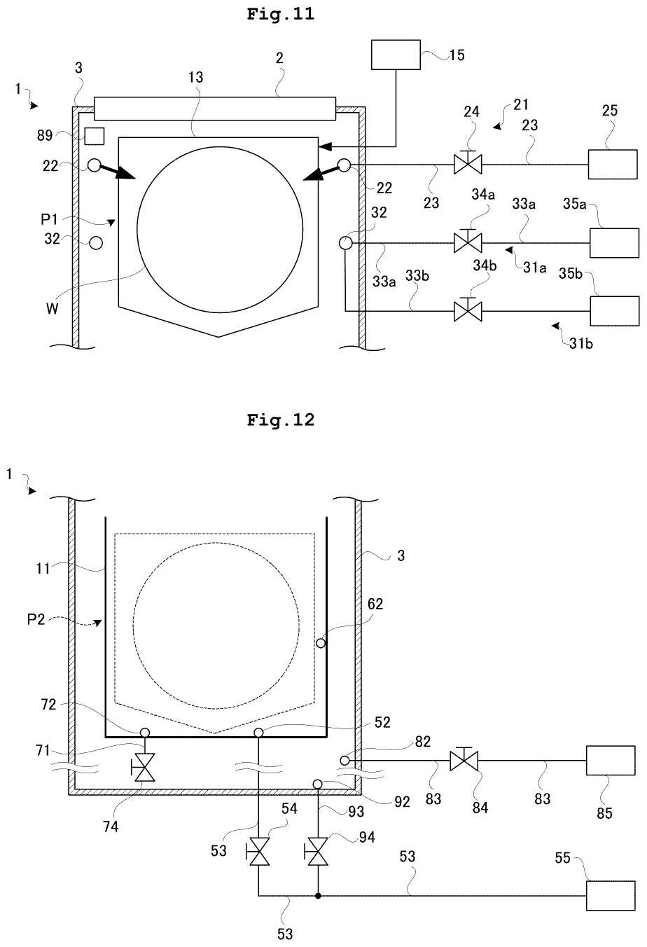

The present modification embodiment is realized regarding a spray direction of the water repellent vapor in the ejection portion 22. That is, as illustrated in FIG. 11, the ejection portion 22 may be configured to spray the water repellent vapor obliquely downward. With such a configuration, it is possible to prevent the water repellent vapor from reaching a ceiling surface or the like in the chamber 3. According to the present modification embodiment, since the water repellent is further prevented from adhering to the inner wall of the chamber 3 by the configuration of the embodiment, it is possible to further prevent the particles from adversely affecting the cleanliness of the substrates W. Similarly, the ejection portion 32 may also be configured to spray the organic solvent vapor obliquely downward.

### Modification Embodiment 5

In the above-described embodiment, the ejection portion 22 related to the water repellent vapor is positioned above the ejection portion 32 related to the organic solvent vapor. However, the positional relationship between the ejection portion 22 and the ejection portion 32 may be reversed. That is, according to the present modification embodiment, the ejection portions 32 related to the organic solvent vapor are positioned above the ejection portions 22 related to the water repellent vapor.

### Modification Embodiment 6

A configuration can be employed in which the piping of the substrate processing apparatus 1 can be omitted as compared with the above-described embodiment. The present modification embodiment is particularly suitable for apparatuses to which the modification embodiment 4 and the modification embodiment 5 are applied, respectively. That is, the present modification embodiment is suitable for a configuration in which the ejection portions 22 related to the water repellent vapor are positioned below the ejection portions 32 related to the organic solvent vapor, and the ejection portions 22 spray the water repellent vapor obliquely downward. In the present modification embodiment, as illustrated in FIG. 12, the processing tank exhaust port 42, the piping 43, the exhaust valve 44, and the pressure reducing pump 45 in the embodiment are omitted, and the inside of the chamber 3 is brought into the pressure reduction state by the pressure reducing pump 85 also in steps S4, S5, and S6. At the time of the pressure reduction, the liquid drain valve 74 is opened, and the water repellent vapor sprayed toward the processing tank 11 flows to the outside of the processing tank 11 through the communication port 72 positioned in the bottom portion of the processing tank 11 and reaches the chamber exhaust port 82. According to the configuration of the present modification embodiment, particles do not affect the cleanliness of the substrate W as in the above-described embodiment.

### Modification Embodiment 7

In the above-described embodiment, step S6 and step S11 are provided as processes of supplying the organic solvent vapor into the chamber 3, but these processes may be omitted. According to the present modification embodiment, the substrate W is less likely to be affected by the particles than in the configuration of the embodiment. However, even in this case, as described in step S5, if the water repellent vapor is suctioned from the bottom portion of the processing tank 11, the water repellent residues do not adhere to the side wall of the chamber 3 or the outer wall of the processing tank 11, and it is possible to prevent the water repellent residues from adversely affecting the cleanliness of the substrates W.

### Modification Embodiment 8

In the above-described embodiment, the processing tank drain port 52 and the chamber drain port 92 communicate with the common drain pump 55, but the present invention is not limited to this configuration. The processing tank drain port 52 and the chamber drain port 92 may be connected to the two drain pumps, respectively, and the piping related to the processing tank drain port 52 and the piping related to the chamber drain port 92 may be provided independently of each other.

### Modification Embodiment 9

In the above-described embodiment, the processing tank exhaust port 42 and the chamber exhaust port 82 are connected to the pipings independent of each other, but the present invention is not limited to this configuration. The processing tank exhaust port 42 and the chamber exhaust port 82 may be connected to a common pressure reducing pump, and the piping related to the processing tank drain port 52 and the piping related to the chamber drain port 92 may be integrated.

### Modification Embodiment 10

The above-described embodiment employs the configuration in which the processing tank exhaust port 42 is provided in the bottom portion of the processing tank 11, but the present invention can also be applied to an apparatus in which an exhaust port is not provided in the bottom portion of the processing tank 11. That is, as the present invention, a configuration may be employed in which it is sufficient that a vent port through which the water repellent vapor is suctioned is provided in the bottom portion of the processing tank 11; for example, a piping connected to a pressure reducing pump outside the chamber 3 may be provided, the piping extending from the opening portion 12a of the processing tank 11 toward the bottom portion of the processing tank 11, and the inside of the processing tank 11 may be subjected to the pressure reduction from the piping.

### Modification Embodiment 11

In the above-described embodiment, the water repellent vapor is supplied into the chamber 3, but the present invention is not limited to this configuration. Instead of the water repellent vapor, a mist-like water repellent may be supplied to the chamber 3.

### REFERENCE SIGNS LIST

1 substrate processing apparatus
2 door
3 chamber
11 processing tank
12a opening portion
13 lifter
15 lifting/lowering mechanism
21 gas supply unit (water repellent supplying means)
31a inert gas supply module
31b organic solvent vapor supply module
40 processing tank pressure-reducing unit (processing tank pressure-reducing means)
42 processing tank exhaust port
43 piping
44 exhaust valve (on-off valve)
45 pressure reducing pump
50 drain unit (draining means)
52 processing tank drain port
53 piping
54 liquid drain valve
55 drain pump
61a pure water supply module
61b liquid organic solvent supply module
71 passage
72 communication port
74 liquid drain valve
81 piping
82 chamber exhaust port
84 adjustment valve
85 pressure reducing pump
92 chamber drain port
93 piping
94 drain valve
101 CPU
102 storage unit
W substrate

1. A substrate processing apparatus that continuously performs water-repellent processing, cleaning processing, and drying processing on a plurality of substrates, the substrate processing apparatus comprising:
a sealable chamber;
a processing tank that is provided in the chamber, stores a cleaning liquid, and has an open upper portion;
a lifter that holds a plurality of substrates and moves up and down between an internal position in the processing tank and a position above the processing tank;
draining means including a processing tank drain port, for draining the cleaning liquid stored in the processing tank;
processing tank pressure-reducing means for evacuating the chamber by reducing a pressure in the processing tank by a processing reducing pump;
water repellent supplying means including ejection port, for supplying a water repellent to the substrates at the position above the processing tank; and
controller for controlling a series of processings for the plurality of substrates, wherein
in a process of performing the water-repellent processing on the plurality of substrates, the controller causes the water repellent supplying means to supply the water repellent to the substrates at the position above the processing tank while evacuating the chamber by causing the draining means to drain a processing liquid in the processing tank, and subsequently causing the processing tank pressure-reducing means to reduce a pressure in the processing tank.

2. The substrate processing apparatus according to claim 1, wherein
the processing tank pressure-reducing means includes an exhaust port formed in the processing tank, a piping having one end connected to the exhaust port, an on-off valve provided in a middle of the piping, and the pressure reducing pump connected to an other end of the piping, and
when the controller causes the water repellent supplying means to supply the water repellent to the substrates at the position above the processing tank, the controller opens the on-off valve and discharges, from the exhaust port, the water repellent collected in the processing tank from an upper opening of the processing tank while causing the pressure reducing pump to perform pressure reduction.

3. The substrate processing apparatus according to claim 2, wherein
the exhaust port is provided in a bottom portion of the processing tank.

4. The substrate processing apparatus according to claim 1, further comprising
organic solvent supplying means including ejection port, for supplying an organic solvent vapor into the chamber.

5. The substrate processing apparatus according to claim 2, wherein
the exhaust port also allows a liquid held in the processing tank to pass therethrough.

6. A substrate processing method for continuously performing water-repellent processing, cleaning processing, and drying processing on a plurality of substrates, wherein
a process of the water-repellent processing includes
evacuating a chamber in which a processing tank is provided by reducing a pressure in the processing tank having an opening at an upper portion through which a plurality of substrates are introduced, and
supplying a water repellent to the plurality of substrates positioned at the upper portion of the processing tank while the processing tank pressure reducing process is executed.

7. The substrate processing method according to claim 6, comprising
cleaning the processing tank with a liquid after the water repellent supplying process.

8. The substrate processing method according to claim 6, comprising
supplying an organic solvent to the processing tank after the water repellent supplying process.
